(19) United States
(12) Patent Application Publication
(10) Pub. No.: US 2005/0088243 A1
(43) Pub. Date: Apr. 28, 2005

(54) PLL circuit reduced phase noise of oscillating signal

(75) Inventor: Kiyoshi Sasai, Fukushima-ken (JP)

Correspondence Address: BRINKS HOFER GILSON & LIONE, P.O. BOX 10395, CHICAGO, IL, 60610, US

(73) Assignee: ALPS ELECTRIC CO., LTD.

(21) Appl. No.: 10/963,072

(22) Filed: Oct. 12, 2004

(30) Foreign Application Priority Data
Oct. 22, 2003 (JP) 2003-362244

(51) Int. Cl. H03L 7/00

(52) U.S. Cl. 331/17

(57) ABSTRACT

An active loop filter has a pre-amplifier for receiving an error signal, a current mirror circuit for supplying a bias current to the pre-amplifier, and an inverting amplifier driven by the pre-amplifier. The pre-amplifier has a first transistor of which the collector is connected to a power supply source and a second transistor of which the collector is connected to the emitter of the first transistor and in which the collector current flows in common with the first transistor, the emitter of the second transistor is connected with the inverting amplifier, the reference current of the current mirror circuit is supplied to the base of the first transistor, the output current of the current mirror circuit is supplied to the base of the second transistors, and the error signal is input to the base of the first transistor.

### BACKGROUND OF THE INVENTION

1. Field of the Invention

The present invention relates to a PLL circuit used in a television tuner, and particularly to a PLL circuit for amplifying a control voltage output from a phase comparator and for supplying the amplified control voltage to a voltage-controlled oscillator.

2. Description of the Related Art

FIG. 3 shows a conventional PLL circuit. The PLL circuit comprises a PLL integrated circuit 10, a voltage-controlled oscillator (VCO) 20, and a loop filter 30. The PLL integrated circuit 10 comprises a reference oscillator 12, variable frequency dividers 14, 16 and a phase comparator 18, which are integrated in one chip. The VCO 20 generates an oscillating signal having a frequency corresponding to a control voltage input to a frequency control voltage input terminal 22 and outputs the oscillating signal to an output terminal 24. The variable frequency divider 14 divides a reference oscillating signal output from the reference oscillator 12 to output the divided reference oscillating signal to one input terminal of the phase comparator 18. The variable frequency divider 16 divides the oscillating signal output from the VCO 20 to output it to the other input terminal of the phase comparator 18.

The phase comparator 18 compares the divided reference oscillating signal of the reference oscillator 12 with the divided oscillating signal of the VCO 20 to output to the loop filter 30 an error signal representing the phase difference obtained from the comparison.

The loop filter 30 comprises an active low pass filter 32 and a lag/lead filter 50 at the next stage thereof. The active low pass filter 32 is comprised by arranging a capacitor C34 in series with a resistor R34 and a capacitor C32 in parallel with the series circuit of the capacitor C34 and the resistor R34 between the input and output terminals of a negative feedback amplifier 38.

The lag/lead filter 50 has R50, R52, and C52. Then, the control voltage output from the lag/lead filter 50 is input to the input terminal 22 of the VCO 20, and the oscillating signal output from the output terminal 24 of the VCO 20 is input to the variable frequency divider 16 (for example, see Japanese unexamined Patent Publication No. 2003-204263 (FIG. 1))

In the above-mentioned configuration, since the active filter is used as the loop filter, the current flows into the loop filter even though the loop filter is in the lock state, and the pulse of the error signal is output from a charge pump (phase comparator) in order to correct the consumption of current. As a result, there is a problem that the noise of the oscillating signal is increased due to the phase noise included in the pulse.

### SUMMARY OF THE INVENTION

The object of the present invention is to reduce the phase noise of the oscillating signal by reducing the current flowing from the phase comparator to the loop filter.

In order to achieve the above object, the PLL circuit according to the present invention comprises a phase comparator for comparing an oscillating signal output from a voltage-controlled oscillator with a reference signal output from a reference oscillator to generate an error signal corresponding to the phase difference therebetween, and an active loop filter for generating a control voltage from the error signal and supplying the control voltage to the voltage-controlled oscillator, wherein an amplifier of the active loop filter has a pre-amplifier for receiving the error signal, a current mirror circuit for supplying a bias current to the pre-amplifier, and an inverting amplifier driven by the pre-amplifier, the pre-amplifier has a first transistor of which the collector is connected to a power supply source and a second transistor of which the collector is connected to the emitter of the first transistor and in which the collector current flows in common with the first transistor, the emitter of the second transistor is connected with the inverting amplifier, the reference current of the current mirror circuit is supplied to the base of the first transistor, the output current of the current mirror circuit is supplied to the base of the second transistor, and the error signal is input to the base of the first transistor.

In addition, a third transistor is inserted between the emitter of the second transistor and the inverting amplifier, the base of the third transistor is connected to the emitter of the second transistor, and the emitter of the third transistor is connected to the input terminal of the inverting amplifier.

Further, the current mirror circuit is composed of a β-assisted current mirror circuit.

In the PLL circuit according to the present invention, an amplifier of the active loop filter has a pre-amplifier for receiving the error signal, a current mirror circuit for supplying a bias current to the pre-amplifier, and an inverting amplifier driven by the pre-amplifier, the pre-amplifier has a first transistor of which the collector is connected to a power supply source, and a second transistor of which the collector is connected to the emitter of the first transistor and in which the collector current flows in common with the first transistor, the emitter of the second transistor is connected with the inverting amplifier, the reference current of the current mirror circuit is supplied to the base of the first transistor, the output current of the current mirror circuit is supplied to the base of the second transistor, and the error signal is input to the base of the first transistor, thereby reducing the current flowing from the phase comparator to the preamplifier and thus reducing the phase noise of the oscillating signal.

In addition, a third transistor is inserted between the emitter of the second transistor and the input terminal of the inverting amplifier, the base of the third transistor is connected to the emitter of the second transistor, and the emitter of the third transistor is connected to the input terminal of the inverting amplifier, thereby the phase noise can be remarkably reduced.

Further, the current mirror circuit comprises a β-assisted current mirror circuit, thereby the phase noise can be remarkably reduced.

### BRIEF DESCRIPTION OF THE DRAWINGS

FIG. 1 is a circuit diagram showing a configuration of a PLL circuit according to a first embodiment of the present invention.

FIG. 2 is a circuit diagram showing a configuration of a PLL circuit according to a second embodiment of the present invention.

FIG. 3 is a circuit diagram showing a configuration of a conventional PLL circuit.

### DESCRIPTION OF THE PREFERRED EMBODIMENT

Hereinafter, embodiments of the present invention will now be described with reference to the drawings.

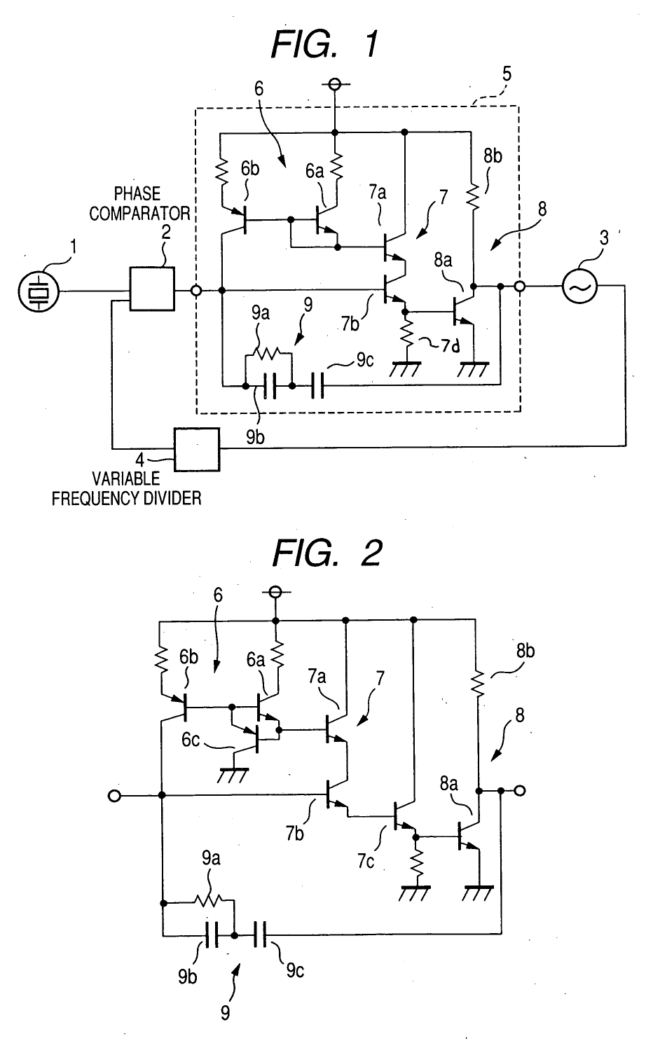

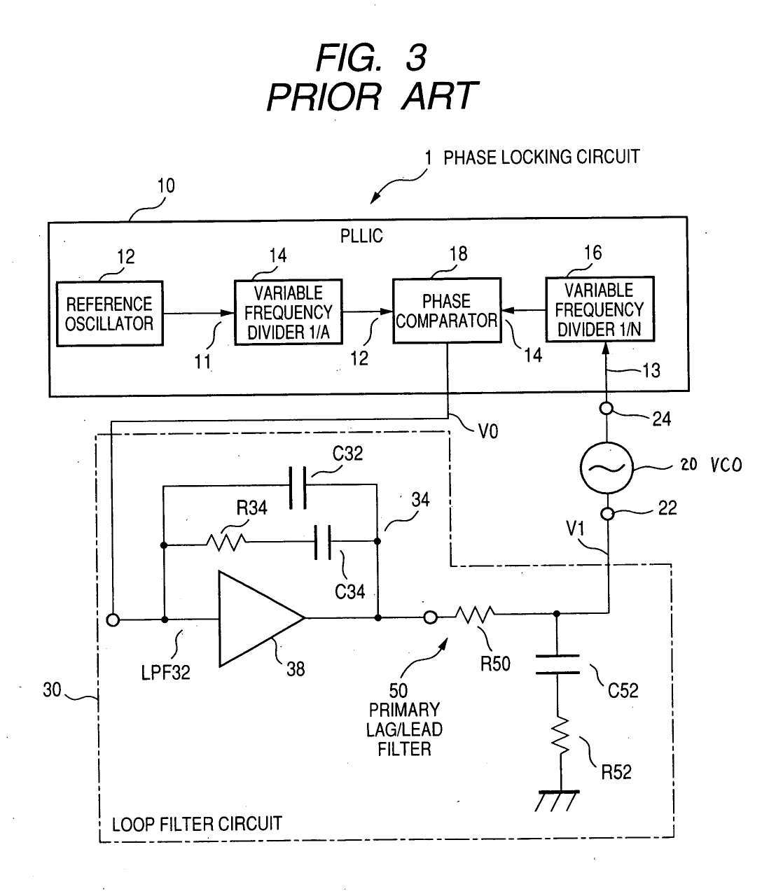

FIG. 1 shows the basic configuration of a PLL circuit according to a first embodiment of the present invention. A reference signal output from a reference oscillator 1 is input to one input terminal of a phase comparator 2 directly or through a frequency divider (not shown). Also, the oscillating signal output from a voltage-controlled oscillator 3 is input to the other terminal of the phase comparator 2 through a variable divider 4. The phase comparator 2 compares the input reference signal with the oscillating signal to output an error signal representing a phase difference to the loop filter 5 as the comparison result. The loop filter 5 generates the control voltage from the input error signal and supplies it the voltage-controlled oscillator 3.

The loop filter 5 comprises an active filter, which comprises a current mirror circuit 6, a pre-amplifier 7 for receiving a bias current from the current mirror circuit 6, an inverting amplifier 8 driven by the pre-amplifier 7, and a feedback circuit 9.

The current mirror circuit 6 is consisted of a standard circuit comprising fifth and sixth PNP transistors 6a, 6b of which the emitters are connected to a power supply source and the bases are connected to each other. The fifth transistor 6a and the sixth transistor 6b have same characteristics. So, in the fifth transistor in which a reference current (collector current) flows, the collector and the base thereof are connected to each other, and the same output current (collector current) as a reference current flows into the sixth transistor 6b.

The pre-amplifier 7 comprises first and second transistors (NPN transistors) serially connected such that a common collector current flows, and the collector of the first transistor 7a is connected to a power supply source. The collector of the second transistor 7b is connected to the emitter of the first transistor 7a, and the emitter of the second transistor 7b is grounded by a resistor 7d or a constant current source (not shown) instead of the resistor 7d so as to construct an emitter follower circuit. Then, the base of the first transistor 7a is supplied with a reference current from the collector of the fifth transistor 6a as a bias current, and the base of the, second transistor 7b is supplied with an output current from the collector of the sixth transistor 6b as a bias current. Also, the first transistor 7a and the second transistor 7b have same characteristics.

The inverting amplifier 8 comprises a fourth transistor 8a, of which the emitter is grounded, the collector is connected to the power supply source through a voltage-drop resistor 8b, and the base is connected to the emitter of the second transistor 7b of the amplifier 7. Also, a feedback circuit 9 is connected between the collector of the fourth transistor 8a and the base of the second transistor. The feedback circuit 9 is comprised by arranging a resister 9b in parallel with a capacitor 9a, and a capacitor 9c in series with the parallel circuit of the resister 9b and capacitor 9a. By this configuration, the loop filter 5 forms the active low pass filter.

The collector of the fourth transistor 8a is connected to the control voltage input terminal of the voltage-controlled oscillator 3. In addition, the output terminal of the voltage-controlled oscillator 3 is connected to the variable frequency divider 4.

By the above-mentioned configuration, since the collector current of the fifth transistor 6a is equal to the collector current of the sixth transistor 6b in the current mirror-circuit 6, as is well known, the sum current (reference current Ir) of the collector current of the fifth transistor 6a and the base current of the two transistors 6a, 6b become approximately equal to the collector current (output current Io) of the sixth transistor 6b. Also, the reference current Ir flows into the base of the first transistor 7a in the pre-amplifier 7, and the output current Io and the current due to the error signal output from the phase comparator 2 flow into the base of the second transistor 7b. Thereby, the voltage according to the error signal is generated across the emitter of the second transistor 7b and thus the inverting amplifier 8 is driven, and the control voltage is output from the collector of the transistor 8a.

In the above-mentioned operation, since the reference current Ir becomes approximately equal to the output current Io, the current absorbed into the base of the second transistor 7b from the phase comparator 2 becomes decreased. In the end terminal of the phase comparator 2, a charge pump, which is made of semiconductor material, is formed. Thus, there is a thermal noise, but the current absorbed into the loop filter 5 from the charge pump is reduced. Accordingly, since the time that the charge pump is turned on is decreased, the noise of the control voltage supplied to the voltage-controlled oscillator 3 is decreased. As a result, it is possible to reduce the phase noise of the oscillating signal.

FIG. 2 shows a second embodiment in which the loop filter 5 has a different configuration. In this configuration, a third transistor 7c forming the emitter follower is inserted between the second transistor 7b and the fourth transistor 8a. Also, the base of the third transistor 7c is connected to the emitter of the second transistor 7b, and the emitter of the third transistor 7c is connected to the base of the fourth transistor 8a in the inverting amplifier 8. Accordingly, since the current flowing from the phase comparator 2 to the base of the second transistor 7b is decreased, the phase noise is remarkably reduced.

Further, in the current mirror circuit 6, by using the seventh transistor (PNP) 6c, the base of the seventh transistor 6c is connected to the collector of the fifth transistor, the emitter of the seventh transistor 6c is connected to the base of the fifth transistor 6a, and the collector of the seventh transistor 6c is grounded, instead of connecting the collector with the base in the fifth transistor 6a. The seventh transistor 6c has the same characteristics as that of the fifth and sixth transistors 6a, 6b. Since the current amplifying ratio β becomes increased in appearance, and the reference current Ir is approximated to the output current Io, these configuration is referred to as the β assisted current mirror circuit. The current flowing from the phase comparator 2 to the second transistor 7b becomes reduced, thereby the phase noise is reduced.

1. A PLL circuit comprising:
a phase comparator for comparing an oscillating signal output from a voltage-controlled oscillator with a reference signal output from a reference oscillator to generate an error signal corresponding to a phase difference between the oscillating signal and the reference signal; and
an active loop filter for generating a control voltage. from the error signal and supplying the control voltage to the voltage-controlled oscillator,
wherein an amplifier of the active loop filter has a pre-amplifier for receiving the error signal, a current mirror circuit for supplying a bias current to the pre-amplifier, and an inverting amplifier driven by the pre-amplifier, the pre-amplifier has a first transistor of which a collector is connected to a power supply source and a second transistor of which a collector is connected to an emitter of the first transistor and in which the collector current flows in common with the first transistor, an emitter of the second transistor is connected with the inverting amplifier, a reference current of the current mirror circuit is supplied to a base of the first transistor, an output current of the current mirror circuit is supplied to a base of the second transistor, and the error signal is input to the base of the first transistor.

2. The PLL circuit according to claim 1, wherein a third transistor is inserted between the emitter of said second transistor and an input terminal of the inverting amplifier, a base of the third transistor is connected to the emitter of the second transistor, and an emitter of the third transistor is connected to the input terminal of the inverting amplifier.

3. The PLL circuit according to claim 1, wherein the current mirror circuit is composed of a β-assisted current mirror circuit.
